(19) United States
(12) Patent Application Publication
(10) Pub. No.: US 2009/0256133 A1
(43) Pub. Date: Oct. 15, 2009

(54) Multiple layer resistive memory

(76) Inventors: Derchang Kau, Cupertino, CA (US); Richard E. Fackenthal, Carmichael, CA (US); Ferdinando Bedeschi, Milano (IT)

Correspondence Address: TROP, PRUNER & HU, P.C., 1616 S. VOSS ROAD, SUITE 750, HOUSTON, TX, 77057-2631, US

(21) Appl. No.: 12/082,137

(22) Filed: Apr. 9, 2008

(51) Int. Cl. H01L 29/06; H01L 21/82

(52) U.S. Cl. 257/5; 438/128; 257/E27.004

(57) ABSTRACT

A resistive memory cell may be composed of four stacked layers. Each layer may be sandwiched by electrodes. Connections may be formed from each of four directions around the stack, for example, aligned with each of four edges where the resistive layers are rectangular.

### BACKGROUND

This invention relates generally to resistive memories.

A resistive memory includes a layer of reversible resistance changing material at a cross-point between transverse electrodes. Examples of such memories include phase change memories and binary metal oxide memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

A binary metal oxide memory includes a binary metal oxide layer between transverse electrodes. The metal layer of the metal oxide may include aluminum or a transition metal, such as nickel, hafnium, iron, copper, or titanium. Examples of binary metal oxides include CuO, TiO₂, HfO₂, Fe₂O₃, and NiO.

### BRIEF DESCRIPTION OF THE DRAWINGS

FIG. 1 is a top plan view of one embodiment of the present invention;

FIG. 2A is a top plan view of a tile in accordance with one embodiment of the present invention situated over the X path in FIG. 1;

FIG. 2B is a depiction of a tile situated over the Y path in FIG. 1 in accordance with one embodiment;

FIG. 3 is an enlarged, perspective view of one embodiment of the present invention;

FIG. 4 is an enlarged, perspective view of another embodiment of the present invention;

FIG. 5 is an enlarged, perspective view of still another embodiment of the present invention;

FIG. 6 is an enlarged, plan view of an array in accordance with one embodiment of the present invention;

FIG. 7 is a partial, enlarged, cross-sectional view of a memory material according to one embodiment; and

FIG. 8 is a system depiction for one embodiment.

### DETAILED DESCRIPTION

In one embodiment, a stack of four or more resistive memory layers may be connected using four or more connections. For example, each connection may be arranged along an edge of one of the four memory layers. For example, if the layers are rectangular, then a connection to each layer may be made along one of four directions, aligned with an edge of a layer.

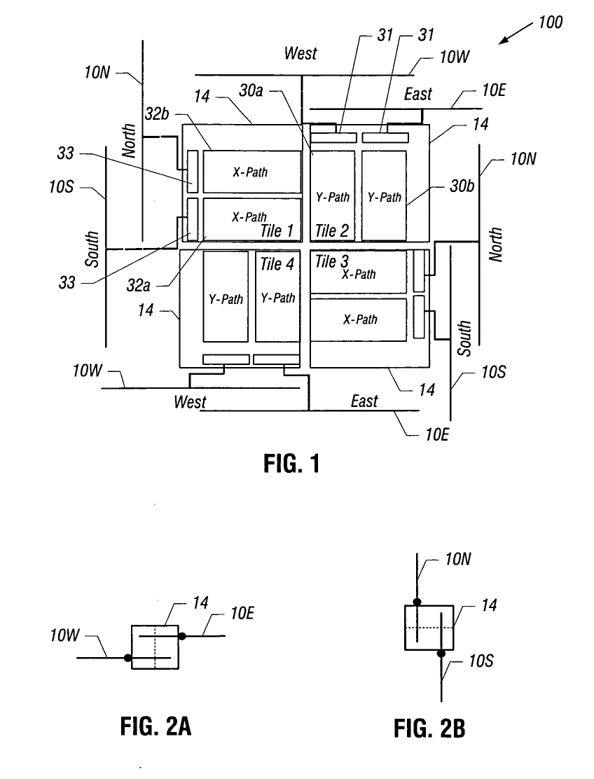

Referring to FIG. 1, a resistive memory array may include a plurality of tiles 14, only four of which are shown in FIG. 1. The four tiles 14 shown in FIG. 1 meet at a corner.

Tile number 1, in the upper left hand corner, is actually positioned over the X path 32b, the X path 32a, and the corresponding X decoders 33. The X decoders 33 are coupled to the south metallization 10S and the north metallization 10N. Likewise, tile number 2 is situated over the Y path 30a, the Y path 30b, and the corresponding Y select decoders 31. Those decoders 31 are coupled to the east metallization 10E and the west metallization 10W. Similarly, tile 3 includes X paths corresponding to tile 1, connected, in turn, to the north metallization 10N and the south metallization 10S. Finally, tile 4 includes Y path elements whose Y select decoders are coupled to the east metallization 10E and the west metallization 10W.

In each case, the actual memory elements of the tile are situated over the X paths 32 and Y paths 30, shown in FIG. 1. A large number of such tiles may be fitted together, repeating the four tile pattern shown to form an array of many tiles.

In some embodiments, a tile 14 may be positioned over the X paths 32, such as indicated in connection with tiles 1 and 3. In such case, the actual connections for the cells of the tile go to the metallizations 10W and 10E as shown in FIG. 2A. In other words, the actual tile memory cells situated over the X paths 32a and 32b are coupled to decoders that are underneath other, adjacent tiles.

Likewise, referring to FIG. 2B, the tile 14 may correspond to tiles 2 and 4 in FIG. 1 and is connected to metallizations 10N and 10S, as depicted. Again, the tile 14 connects to Y path elements 30 under a different, adjacent tile, rather than to those Y path elements directly under the tile itself.

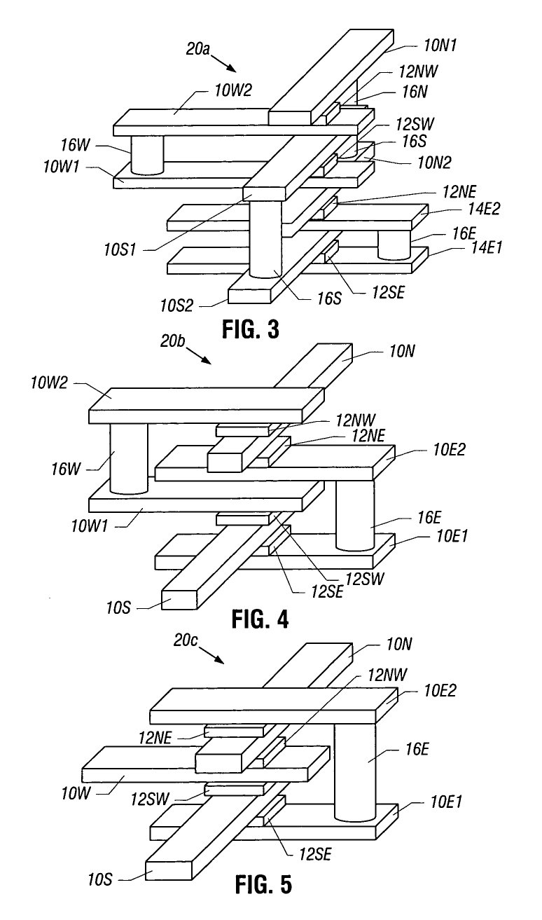

Moving to FIG. 3, in accordance with one embodiment, four stacked cells within a tile array have connections to the different metallizations. The uppermost phase change material 12NW is over the next uppermost memory material 12SW, over the next lower memory material 12NE, over the next lowermost memory material 12SE. The memory material 12NW is coupled between metallization 10N1, extending in the north direction, and metallization 10W2, extending in the west direction. (The compass directions given are not actual physical compass directions, but are relative directions, given for ease of understanding only). Similarly, the memory material 12SW is coupled between a metallization 10W1, extending in the west direction. In the same fashion, the memory material 12NE is sandwiched between metallization 10N2 and metallization 14E2. Finally, the memory material 12SE is situated between a metallization 10S2, extending in the south direction, and a metallization 14E1, extending in the east direction.

The various metallizations 10 may then be coupled together by pillars or vias 16. For example, the metallizations 10N1 and 10N2 are coupled by via 16N. The metallizations 10W2 and 10W1 are coupled together by via 16W. The metallization 10S1 and 10S2 are coupled together by metallization 16S. Finally, the metallizations 14E2 and 14E1 are coupled together by the via 16E.

Thus, in one embodiment, pairs of similarly directionally oriented metallizations 10 are coupled together by vias 16 in order to operate a stack of four different resistive memory cells as one stacked unit. The embodiment shown in FIG. 3 includes four layers of memories with four vias and eight metallizations.

Referring next to the embodiment of FIG. 4, there are two bi-memory layers. The first bi-memory layer includes the memory material 12NW and the memory material 12NE. The memory material 12NW is sandwiched between metallization 10N and the metallization 10W2, extending north and west, respectively. The other element of the bi-layer, memory material 12NE, is sandwiched between the metallization 10N and the eastwardly directed metallization 10E2.

The second bi-layer includes memory material 12SW and memory material 12SE. Memory material 12SW is sandwiched between southerly metallization 10S and westerly metallization 10W1. The memory material 12SE is coupled between metallization 10S and easterly metallization 10E1. Only two vias are used, including the via 16W, between metallizations 10W2 and 10W1, and the metallization 16E, between the metallizations 10E2 and 10E1. The via 16E is always a row and the via 16W is always a column, in one embodiment.

As a third example, shown in FIG. 5, four symmetrical memory layers are provided in accordance with one embodiment. The first memory material 12NE is sandwiched between metallization 10E2 and metallization 10N. The second memory material 10NW is sandwiched between metallization 10N and metallization 10W, extending in northerly and westerly directions, respectively. The memory material 10SW is situated between southerly directed metallization 10S and westerly directed metallization 10W.

Finally, the memory material 12SE is situated between southerly directed metallization 10S and easterly directed metallization 10E1. Only one via 16E is used, in this case—between metallizations 10E1 and 10E2. Thus, a total of only five metallization and one via are utilized in the embodiment of FIG. 5. In this embodiment, either all levels of pitch cells alternate between column and row or memory cells are symmetric.

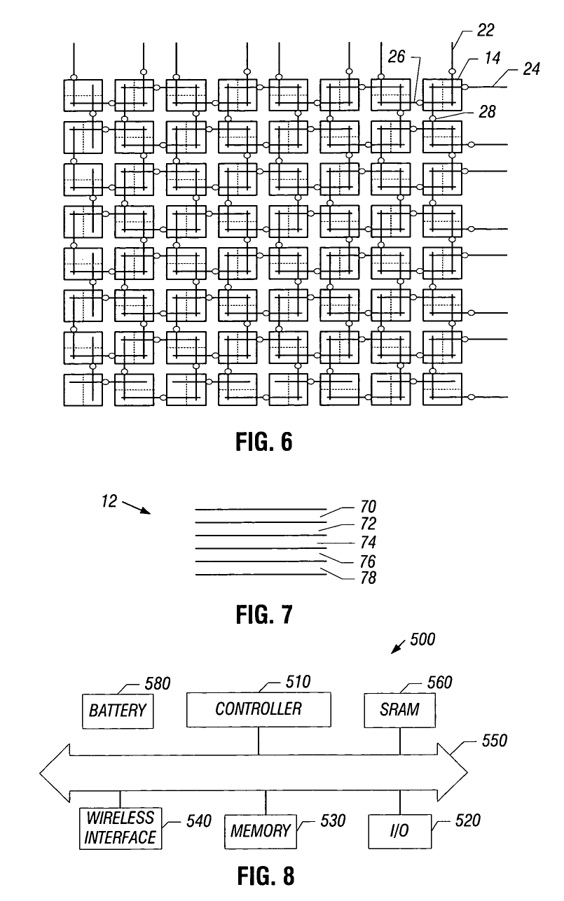

Referring next to FIG. 6, the connections of each tile 14 are illustrated. Each tile may be in any of the forms shown in FIGS. 3-5 or in other embodiments, with still other variations. Thus, the tiles 14a, 14b, or 14c may be any one of the tiles 14 shown in FIG. 6. Each tile 14 shown in FIG. 6 has a north metallization 22, an east metallization 24, a west metallization 26, and a south metallization 28. Thus, the north metallization 22 may correspond to the metallizations 10N1 and 10N2, coupled by the via 16N, in the embodiment of FIG. 3. In the embodiment of FIG. 4, the metallization 10N may correspond to the metallization 22.

The memory material 12 may be any resistive memory material including a phase change material, such as a chalcogenide, or other types of resistive memory elements including a binary metal oxide, such as TiO or CuO.

Referring to FIG. 7, a more detailed depiction of the memory material 12 is indicated. In one embodiment, the memory material 12 may include a top electrode interface 70, such as titanium nitride. A selector 72 may be an ovonic threshold switch or a thin film polysilicon based p/n junction diode, as two examples. An intermediate electrode interface 74 provides an interface to delineate the selector and the storage element. The storage element 76 may be an ovonic unified memory including a chalcogenide or any other resistive memory element, such as a binary metal oxide. The bottom electrode 78 may be titanium nitride or titanium silicon nitride, to mention two examples.

Programming to alter the state or phase of the memory material 12 that is a phase change material may be accomplished by applying voltage potentials to the electrodes 70 and 78, thereby generating a voltage potential across a memory element including a phase change material 76. When the voltage potential is greater than the threshold voltages of the selector 72 and storage element 76, then an electrical current may flow through the storage element 76 in response to the applied voltage potentials, and may result in heating of the storage element 76.

This heating may alter the memory state or phase of the element 76, in one embodiment. Altering the phase or state of the element 76 may alter the electrical characteristic of memory material, e.g., the resistance of the material may be altered by altering the phase of the memory material.

In the “reset” state, the storage element may be in an amorphous or semi-amorphous state and in the “set” state, memory material may be in an a crystalline or semi-crystalline state. The resistance of the storage element in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, the storage element may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

An ovonic threshold switch is either on or off depending on the amount of voltage potential applied across the switch and, more particularly, whether the current through the switch exceeds its threshold current or voltage, which then triggers the device into an on state. The off state may be substantially electrically non-conductive and the on state may be a substantially conductive state with less resistance than the off state.

In the on state, the voltage across the switch, in one embodiment, is equal to its holding voltage V_{hold}+IRₒₙ, where Rₒₙ is the dynamic resistance from the extrapolated X axis intercept V_{hold}. For example, an ovonic threshold switch may have a threshold voltage Vₜₕ and, if a voltage potential less than the threshold voltage of the switch is applied across the switch, then the switch may remain off or in a relatively high resistant state so that little or no electrical current passes.

Alternatively, if a voltage potential greater than the threshold voltage of the selector 72 is applied across the device, then the device may turn on, i.e., operate in a relatively low resistance state so that significant electrical current passes through the switch. In other words, one or more series connected switches may be in a substantially electrically non-conductive state at less than a predetermined voltage, e.g., the threshold voltage as applied across a switch. The switch may be in a substantially conductive state if greater than a predetermined voltage is applied across the switch.

In one embodiment, each switch may comprise a switch material that is a chalcogenide alloy. The switch material may be a material in a substantial amorphous state positioned between two electrodes that may be repeatedly and reversibly switched between a higher resistance off state that is greater than about 10 megaOhms and a relatively lower resistance on state that is about 10 Ohms in series with the holding voltage by the application of electrical current or potential.

Each switch is a two-terminal device that has an IV curve similar to that of a phase change memory element that is in an amorphous state. However, unlike a phase change memory element, the ovonic threshold switch does not change phase. That is, the switching material of the ovonic threshold switch is not a programmable material and, as a result, the switch may not be a memory device capable of storing information. For example, the switching material may remain permanently amorphous and the IV characteristics may remain the same throughout the operating life.

In the low voltage, a low electric field mode, where the voltage applied across the switch is less than the threshold voltage Vth, the switch may be off or non-conducting and exhibits a relatively high resistance (greater than about 10 megaOhms). The switch may remain in the off state until its sufficient voltage, namely, the threshold voltage, is applied or a sufficient current is applied, namely, the threshold current, that switches the device to a conductive relatively low resistance on state. After a voltage potential of greater than about the threshold voltage is applied across the device, the voltage potential across the device may drop or snapback to a holding voltage V_{hold}. Snapback may refer to the voltage difference between the threshold voltage and the holding voltage of the switch.

In the on state, the voltage potential across the switch may remain close to the holding voltage as current passing through the switch is increased. The switch may remain on until the current through the switch drops below a holding current. Below this value, the switch may turn off and return to a relatively high resistance, non-conductive off state, until the threshold voltage and current are again exceeded.

In some embodiments, only one selector 72 may be used. In other embodiments, two or more series connected selectors may be used.

Turning to FIG. 8, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

For example, more than four layers of chalcogenide may be used in some embodiments. The layers need not be rectangular, especially when more than four layers are used. In some embodiments, the number of layer edges and the number of layers and the number of connections per stack may be the same.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a vertical stack of at least four resistive memory layers; and
providing at least four connections to said vertical stack for accessing the layers of said stack.

2. The method of claim 1 including forming layers with four rectangular edges.

3. The method of claim 2 including forming a connection to each layer, said connections extending in four different directions from said stack.

4. The method of claim 1 including forming a memory array of tiles made up of a plurality of said stacks.

5. The method of claim 4 including forming row and column decoders under said tiles.

6. The method of claim 5 including coupling a decoder under one of said tiles to stacks in a different tile.

7. The method of claim 1 including providing a pair of parallel electrodes sandwiching each layer.

8. The method of claim 7 including angling the electrodes of one layer relative to electrodes over an underlying layer.

9. The method of claim 8 including forming electrodes extending in the same direction from two different layers of the stack.

10. The method of claim 1 including forming said layers of phase change material.

11. A resistive memory comprising:
a vertical stack including at least four resistive memory layers; and
at least four electrical connections to said vertical stack to enable each of said layers to be accessed.

12. The memory of claim 11 wherein said layers have four rectangular edges.

13. The memory of claim 12 including an electrical connection to each layer, said connections extending in four different locations from said stack.

14. The memory of claim 11 including an array of tiles, each tile made up of a plurality of said stacks.

15. The memory of claim 14 including row and column decoders under said tiles.

16. The memory of claim 15 including a decoder under one of said tiles coupled to stacks in a different tile.

17. The memory of claim 11 including a pair of parallel electrodes sandwiching each layer.

18. The memory of claim 17 including electrodes of one layer angled relative to electrodes over underlying layers.

19. The memory of claim 18 including electrodes extending in the same direction from two different layers of the stack.

20. The memory of claim 11 including a layer having a phase change material.

21. The memory of claim 20 including a selector in series with said phase change material.

22. The memory of claim 21 wherein said selector is an ovonic threshold switch.

23. A resistive memory comprising:
at least four vertically spaced resistive memory material layers;
a plurality of conductors, sandwiching one or more of said layers; and
one of said conductors extending in each of four different directions.

24. The memory of claim 23 wherein said memory is a phase change memory.

25. The memory of claim 23 wherein each of said directions is perpendicular to another of said directions.

26. The memory of claim 23 wherein each layer is sandwiched by two conductors.

27. The memory of claim 23 wherein each layer includes a selector.

28. The memory of claim 27 wherein said selector is an ovonic threshold switch.

29. A system comprising:
a processor; and
a resistive memory coupled to said processor, said memory including a cell with at least four stacked resistive memory layers and a plurality of electrodes arranged in two transverse directions, sandwiching each layer.

30. The system of claim 29 wherein each layer includes a selector.
